(19) United States
(12) Patent Application Publication
(10) Pub. No.: US 2019/0305740 A1
(43) Pub. Date: Oct. 3, 2019

(54) Gain-Dependent Impedance Matching and Linearity

(71) Applicant: Qualcomm Incorporated, San Diego, CA (US)

(72) Inventors: Alaaeldien Mohamed Abdelrazek Medra, San Diego, CA (US); David Zixiang Yang, San Diego, CA (US); Kevin Hsi Huai Wang, San Diego, CA (US)

(21) Appl. No.: 16/446,492

(22) Filed: Jun. 19, 2019

Related U.S. Application Data
(63) Continuation-in-part of application No. 16/200,405, filed on Nov. 26, 2018.
Application No. 16/200,405 is a continuation-in-part of application No. 15/940,808, filed on Mar. 29, 2018.
(60) Provisional application No. 62/588,222, filed on Nov. 17, 2017.

(51) Int. Cl. H03F 9/02; H03F 3/195; H03F 1/56; H03F 1/22; H03H 7/38; H04B 1/00

(52) U.S. Cl. CPC H03F 9/02; H03F 3/195; H03F 1/565; H03F 2200/372; H03H 7/38; H04B 1/006; H03F 1/223

(57) ABSTRACT

An integrated circuit is disclosed for gain-dependent impedance matching and linearity. The integrated circuit includes at least two amplifier branches, an input inductor, and at least two degeneration inductors. Each amplifier branch includes a node, an input transistor, and a cascode stage connected between a drain of the input transistor and the node. Respective nodes of the at least two amplifier branches are connected together and respective gates of the input transistors of the at least two amplifier branches are connected together. The input inductor is connected to the respective gates, and the at least two degeneration inductors are connected between respective sources of the input transistors of the at least two amplifier branches and a ground. The at least two degeneration inductors are configured to establish a magnetic coupling with the input inductor and establish another magnetic coupling between each other.

### CROSS-REFERENCE TO RELATED APPLICATION(S)

This application is a continuation-in-part of U.S. application Ser. No. 16/200,405, filed 26 Nov. 2018—the entire contents of which are herein incorporated by reference for all purposes, which is a continuation-in-part of U.S. application Ser. No. 15/940,808, filed 29 Mar. 2018—the entire contents of which are herein incorporated by reference for all purposes, which claims the benefit of U.S. Provisional Application No. 62/588,222, filed 17 Nov. 2017—the entire contents of which are herein incorporated by reference for all purposes.

### TECHNICAL FIELD

This disclosure relates generally to amplifiers and, more specifically, to having magnetically-coupled inductors that enhance impedance matching and linearity of low-noise amplifiers for different gains.

### BACKGROUND

Electronic devices use radio-frequency (RF) signals to communicate information. These radio-frequency signals enable users to talk with friends, download information, share pictures, remotely control household devices, receive global positioning information, employ radar for detection and tracking, or listen to radio stations. As a distance over which these radio-frequency signals travel increases, it becomes increasingly challenging to distinguish the radio-frequency signals from background noise. To address this issue, electronic devices use low-noise amplifiers (LNAs), which amplify a radio-frequency signal without introducing significant additional noise. Performance of a low-noise amplifier depends on several factors, including impedance matching and linearity.

As electronic devices communicate over different distances, desired amounts of amplification by the low-noise amplifier can vary. Consider a mobile phone communicating with a base station. If the mobile phone is far from the base station, a strength of the radio-frequency signal may be low; thus, it may be desirable for the low-noise amplifier to provide more amplification. In contrast, if the mobile phone is close to the base station, the strength of the radio-frequency signal may be high; thus, it may be desirable for the low-noise amplifier to provide less amplification. It becomes challenging, however, to design a low-noise amplifier to support different amounts of amplification, which are referred to as different gain modes.

### SUMMARY

An integrated circuit is disclosed that implements gain-dependent impedance matching and linearity. In particular, three or more magnetically-coupled inductors are integrated within a low-noise amplifier to adjust an input impedance and linearity of the low-noise amplifier according to a gain that the low-noise amplifier provides. By enabling the input impedance to change across different gain modes, the magnetically-coupled inductors can reduce losses and noise levels that are associated with the low-noise amplifier and thereby improve wireless communication performance.

In an example aspect, an integrated circuit is disclosed. The integrated circuit includes at least two amplifier branches, an input inductor, at least two degeneration inductors, a first input terminal, and a wideband switch module. Each amplifier branch of the at least two amplifier branches includes a node, an input transistor, and a cascode stage. Respective nodes of the at least two amplifier branches are connected together. The input transistor has a gate, a source, and a drain. Respective gates of the input transistors of the at least two amplifier branches are connected together. The cascode stage is connected between the drain of the input transistor and the node. The input inductor is connected to the respective gates of the input transistors of the at least two amplifier branches. The at least two degeneration inductors are connected between respective sources of the input transistors of the at least two amplifier branches and a ground. The at least two degeneration inductors are configured to establish a magnetic coupling with the input inductor. The at least two degeneration inductors are also configured to establish another magnetic coupling between each other. The wideband switch module comprises a switch and at least one grounding switch. The switch is connected between the first input terminal and an output node of the input inductor. The output node of the input inductor is connected to the respective gates of the input transistors of the at least two amplifier branches. The at least one grounding switch is connected between at least one input node of the input inductor and the ground.

In an example aspect, an integrated circuit is disclosed. The integrated circuit includes a first input terminal, a second input terminal, and at least two amplifier branches. The first input terminal is configured to connect to a band-pass filter. The second input terminal is configured to bypass the band-pass filter. The at least two amplifier branches include a first amplifier branch and a second amplifier branch. The first amplifier branch has a first node, a first input transistor, and a first cascode stage. The first input transistor has a first gate, a first source, and a first drain. The first gate is connected to the first input terminal and the first source is connected to a ground. The first cascode stage is connected between the first drain and the first node. The second amplifier branch has a second node, a second input transistor, and a second cascode stage. The second input transistor has a second gate, a second source, and a second drain. The second gate is connected to the first gate and the second source is connected to the ground. The second cascode stage is connected between the second drain and the second node. The second node is connected to the first node. The integrated circuit also includes inductive means for magnetically coupling together the first gate, the second gate, the first source, and the second source. The inductive means is configured to produce, based on a first current that flows from the first source to the ground and a second current that flows from the second source to the ground, at least a portion of a third current that flows from the first input terminal towards the first gate and the second gate. The integrated circuit additionally includes first switching means for selectively connecting the first gate and the second gate to the first input terminal or the second input terminal.

In an example aspect, a method for gain-dependent impedance matching and linearity is disclosed. The method includes generating a mutual inductance between multiple degeneration inductors that are connected between multiple amplifier branches and a ground. The method also includes generating another mutual inductance between an input inductor and the multiple degeneration inductors. The input inductor is connected to the multiple amplifier branches and an input terminal. Based on the mutual inductance and the other mutual inductance, the method additionally includes causing an input impedance of an amplifier to facilitate passing of a communication signal from the input terminal to the amplifier. The amplifier includes the multiple degeneration inductors, the multiple amplifier branches, and the input inductor. The method further includes amplifying the communication signal using one or more of the multiple amplifier branches. The amplifying of the communication signal comprises operating the multiple amplifier branches in a common-gate configuration by providing the communication signal to an output node of the input inductor and grounding an input node of the input inductor. The output node is connected to the multiple amplifier branches and the input node is different than the output node.

In an example aspect, an apparatus is disclosed. The apparatus includes a node, a band-pass filter, an amplifier circuit, an input inductor, at least two degeneration inductors, a narrowband switch module, and a wideband switch module. The node is configured to accept a received signal. The band-pass filter is configured to filter the received signal to produce a filtered signal. The amplifier circuit includes at least two amplifier branches. The amplifier circuit is configured to amplify an input signal using one or more of the at least two amplifier branches. The input inductor has an input node and an output node. The output node is coupled to the amplifier circuit. The at least two degeneration inductors are respectively connected between the at least two amplifier branches of the amplifier circuit and a ground. The at least two degeneration inductors are magnetically coupled to each other and to the input inductor with respective coupling coefficients. The narrowband switch module is connected between the band-pass filter and the input node of the input inductor. The narrowband switch module is configured to provide, to the input node of the input inductor, the filtered signal as the input signal. The wideband switch module is connected to the node, the output node of the input inductor, and the input node of the input inductor. The wideband switch module is configured to provide, to the output node of the input inductor, the received signal as the input signal and to connect the input node of the input inductor to the ground.

### BRIEF DESCRIPTION OF DRAWINGS

FIG. 1 illustrates an example environment for gain-dependent impedance matching and linearity.

FIG. 2 illustrates a portion of an example wireless transceiver for gain-dependent impedance matching and linearity.

FIG. 3-1 illustrates an example implementation of a portion of the wireless transceiver for gain-dependent impedance matching and linearity.

FIG. 3-2 illustrates example connections between multiple narrowband switch modules and an input inductor for gain-dependent impedance matching and linearity.

FIG. 3-3 illustrates example connections between a wideband switch module and an input inductor for gain-dependent impedance matching and linearity.

FIG. 4 illustrates an example low-noise amplifier for gain-dependent impedance matching and linearity.

FIG. 5 illustrates an example integrated circuit for gain-dependent impedance matching and linearity.

FIG. 6 illustrates example inductors for implementing gain-dependent impedance matching and linearity.

FIG. 7 is a flow diagram illustrating an example process for gain-dependent impedance matching and linearity.

### DETAILED DESCRIPTION

Electronic devices use low-noise amplifiers (LNAs) to support radio-frequency communication. As electronic devices communicate over different distances, desired amounts of amplification by a low-noise amplifier can vary for different gain modes. It becomes challenging, however, for the low-noise amplifier to achieve target impedance matching and linearity across the different gain modes. In particular, some techniques for achieving impedance matching and linearity at one gain mode may not be desirable for another gain mode. As such, performance of the low-noise amplifier may decrease across different gain modes, thereby decreasing the wireless communication performance of the electronic device.

To achieve a target input impedance, some low-noise amplifiers use external (e.g., off-chip) impedance-matching circuits, which increases a size of a radio-frequency front end (RFFE) module and the low-noise amplifier. The increased size is due to, for example, discrete electrical components, routing connections, connection bumps, and electrostatic discharge (ESD) protection circuits. Other techniques use two magnetically-coupled inductors implemented on the integrated circuit of the low-noise amplifier to achieve some measure of impedance matching and linearity. Both of these techniques, however, are unable to dynamically adjust the impedance matching and linearity according to different gains.

In contrast, example approaches are described herein for gain-dependent impedance matching and linearity. In particular, three or more magnetically-coupled inductors are implemented within the low-noise amplifier. As the low-noise amplifier provides different gains, an inductance provided by the magnetically-coupled inductors changes, thereby improving impedance matching and linearity across different gains of the low-noise amplifier.

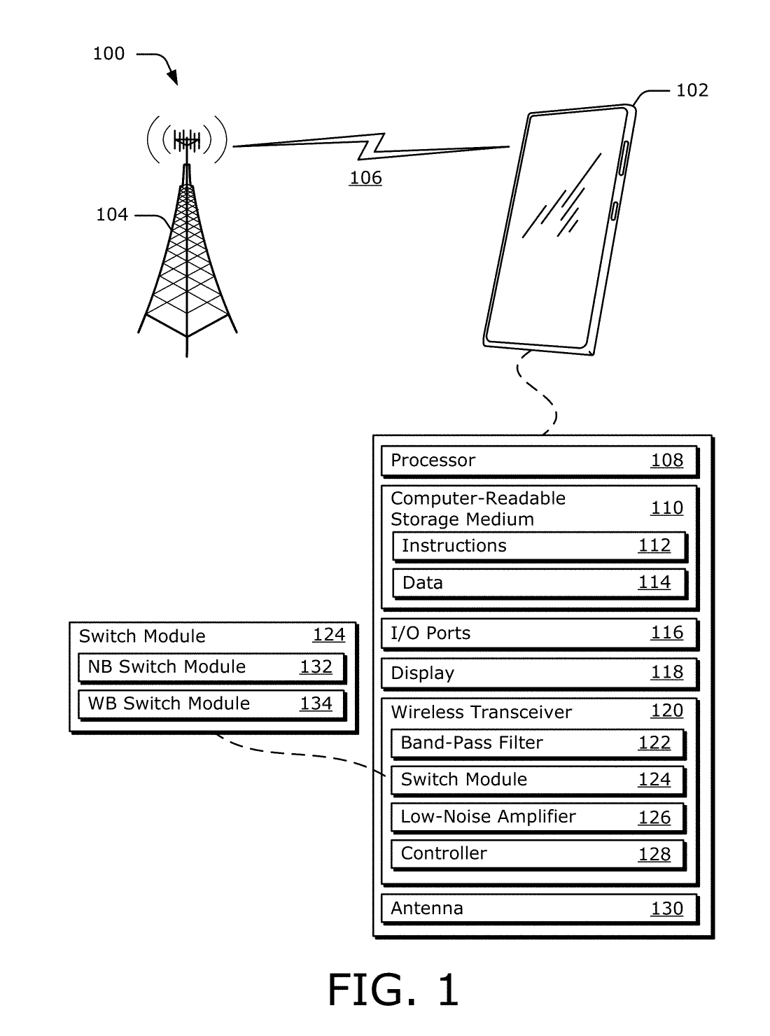

FIG. 1 illustrates an example environment 100, which includes a computing device 102 that communicates with a base station 104 through a wireless communication link 106 (wireless link 106). In this example, the computing device 102 is implemented as a smart phone. However, the computing device 102 may be implemented as any suitable computing or electronic device, such as a modem, cellular base station, broadband router, access point, cellular phone, gaming device, navigation device, media device, laptop computer, desktop computer, tablet computer, server, network-attached storage (NAS) device, smart appliance, vehicle-based communication system, Internet-of-Things (IoT) device, and so forth.

The base station 104 communicates with the computing device 102 via the wireless link 106, which may be implemented as any suitable type of wireless link. Although depicted as a tower of a cellular network, the base station 104 may represent or be implemented as another device, such as a satellite, cable television head-end, terrestrial television broadcast tower, access point, peer-to-peer device, mesh network node, fiber optic line, and so forth. Therefore, the computing device 102 may communicate with the base station 104 or another device via a wired connection, a wireless connection, or a combination thereof.

The wireless link 106 can include a downlink of data or control information communicated from the base station 104 to the computing device 102 and an uplink of other data or control information communicated from the computing device 102 to the base station 104. The wireless link 106 may be implemented using any suitable communication protocol or standard, such as second-generation (2G), third-generation (3G), fourth-generation (4G), or fifth-generation (5G) cellular; IEEE 802.11 ((e.g., Wi-Fi); IEEE 802.15 (e.g., Bluetooth™); IEEE 802.16 (e.g., WiMAX™); and so forth.

As illustrated, the computing device 102 includes at least one processor 108 and at least one computer-readable storage medium 110 (CRM 110). The processor 108 may include any type of processor, such as an application processor or multi-core processor, that is configured to execute processor-executable code stored by the CRM 110. The CRM 110 may include any suitable type of data storage media, such as volatile memory (e.g., random access memory (RAM)), non-volatile memory (e.g., Flash memory), optical media, magnetic media (e.g., disk or tape), and so forth. In the context of this disclosure, the CRM 110 is implemented to store instructions 112, data 114, and other information of the computing device 102, and thus does not include transitory propagating signals or carrier waves.

The computing device 102 may also include input/output ports 116 (I/O ports 116) and a display 118. The I/O ports 116 enable data exchanges or interaction with other devices, networks, or users. The I/O ports 116 may include serial ports (e.g., universal serial bus (USB) ports), parallel ports, audio ports, infrared (IR) ports, and so forth. The display 118 presents graphics of the computing device 102, such as a user interface associated with an operating system, program, or application. Alternately or additionally, the display 118 may be implemented as a display port or virtual interface, through which graphical content of the computing device 102 is presented.

A wireless transceiver 120 of the computing device 102 provides connectivity to respective networks and other electronic devices connected therewith. Alternately or additionally, the computing device 102 may include a wired transceiver, such as an Ethernet or fiber optic interface for communicating over a local network, intranet, or the Internet. The wireless transceiver 120 may facilitate communication over any suitable type of wireless network, such as a wireless local-area network (WLAN), peer-to-peer (P2P) network, mesh network, cellular network, wireless wide-area-network (WWAN), and/or wireless personal-area-network (WPAN). In the context of the example environment 100, the wireless transceiver 120 enables the computing device 102 to communicate with the base station 104 and networks connected therewith.

The wireless transceiver 120 includes circuitry and logic, such as filters, switches, amplifiers, mixers, and so forth, for conditioning signals that are transmitted or received via at least one antenna 130. The wireless transceiver 120 may also include logic to perform in-phase/quadrature (I/Q) operations, such as synthesis, encoding, modulation, decoding, demodulation, and so forth. In some cases, components of the wireless transceiver 120 are implemented as separate receiver and transmitter entities. Additionally or alternatively, the wireless transceiver 120 can be realized using multiple or different sections to implement respective receiving and transmitting operations (e.g., separate receive and transmit chains). The wireless transceiver 120 also includes a baseband modem (not shown) to process data and/or signals associated with communicating data of the computing device 102 over the antenna 130. The baseband modem may be implemented as a system-on-chip (SoC) that provides a digital communication interface for data, voice, messaging, and other applications of the computing device 102. The baseband modem may also include baseband circuitry to perform high-rate sampling processes that can include analog-to-digital conversion, digital-to-analog conversion, gain correction, skew correction, frequency translation, and so forth.

As shown, the wireless transceiver includes at least one band-pass filter 122, at least one switch module 124, at least one low-noise amplifier (LNA) 126, and at least one controller 128. The band-pass filter 122 can be implemented with acoustic resonators, such as surface acoustic wave (SAW) resonators or bulk-acoustic wave (BAW) resonators. In some cases, the band-pass filter 122 can include multiple band-pass filters, which have different passbands (e.g., pass different frequency bands). The different passbands can be associated with one frequency band range or different frequency band ranges. Generally, each of the multiple band-pass filters can pass at least a portion of frequencies within a frequency band range associated with the passband. The band-pass filter 122 filters a signal that is received via the antenna 130 to produce a narrowband filtered signal.

The switch module 124 can include at least one narrowband switch module 132 or at least one wideband switch module 134 (or both). The term “narrowband” within the narrowband switch module 132 and the term “wideband” within the wideband switch module 134 refer to different operational modes of the wireless transceiver 120 for which the narrowband switch module 132 and the wideband switch module 134 are selectively enabled. In general, an operational mode that receives a communication signal with a first bandwidth enables the narrowband switch module 132 while another operational mode that receives another communication signal with a second bandwidth that is larger than the first bandwidth enables the wideband switch module 134.

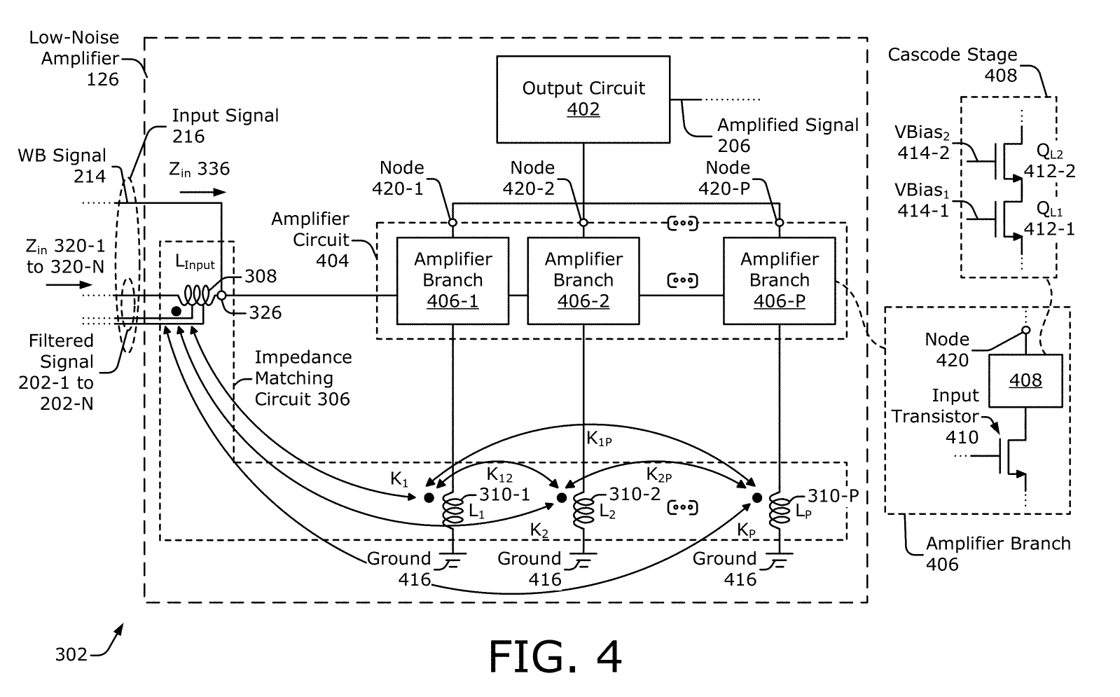

As further described with respect to FIG. 4, the narrowband switch module 132 causes the low-noise amplifier 126 to be in a common-source configuration, and the wideband switch module 134 causes the low-noise amplifier 126 to be in a common-gate configuration. In the common-source configuration, the low-noise amplifier 126 can provide narrowband input impedance matching with better noise figure performance relative to the common-gate configuration. However, the common-gate configuration can provide wideband input impedance matching with better linearity relative to the common-source configuration. The wideband switch module 134 also enables gm-boosting, which improves the noise-figure performance of the common-gate configuration by providing at least a portion of an input signal to one or more gates of input transistors within the low-noise amplifier 126 to increase the effective transconductance (gm).

Instead of implementing multiple low-noise amplifiers, performance of the low-noise amplifier 126 can be tailored to support multiple operational modes of the wireless transceiver 120 by selectively providing an input signal via the narrowband switch module 132 or the wideband switch module 134. For a narrowband operational mode (e.g., a 2G, 3G, or 4G mode), the narrowband switch module 132 is used to cause the low-noise amplifier 126 to be in the common-source configuration, for instance. Alternatively, during a wideband operational mode (e.g., a 5G or carrier aggregation mode), the wideband switch module 134 is used to cause the low-noise amplifier 126 to be in the common-gate configuration. The common-source configuration and the common-gate configuration of the low-noise amplifier 126 are further described with respect to FIG. 4.

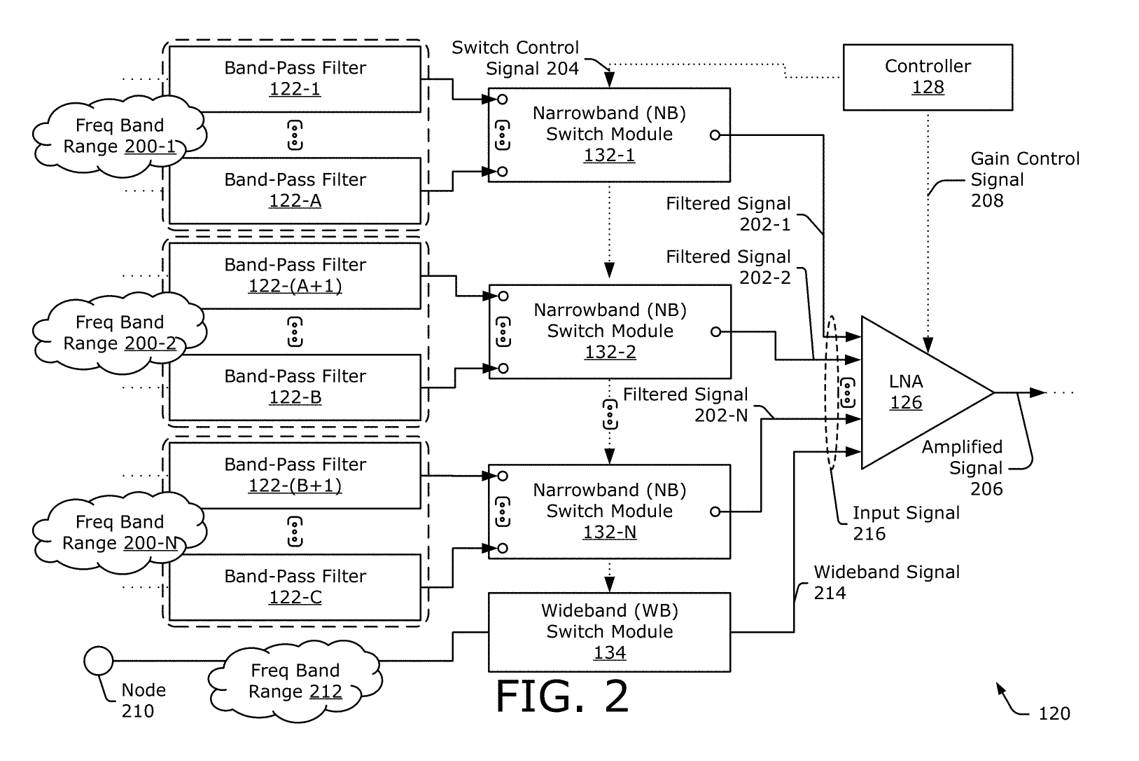

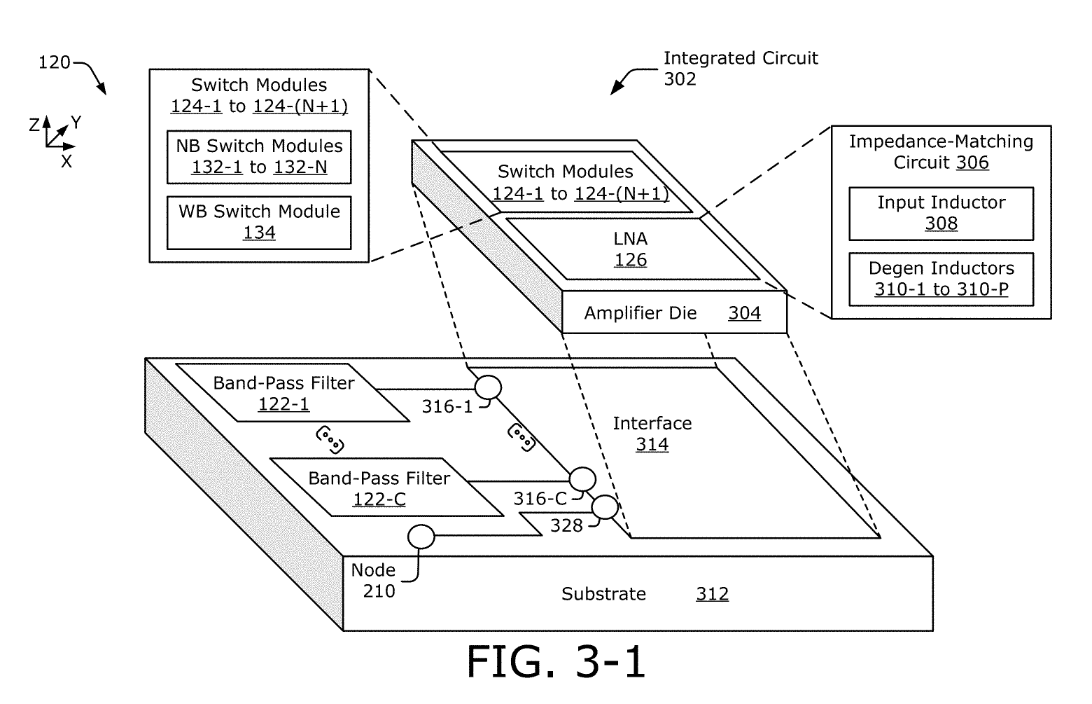

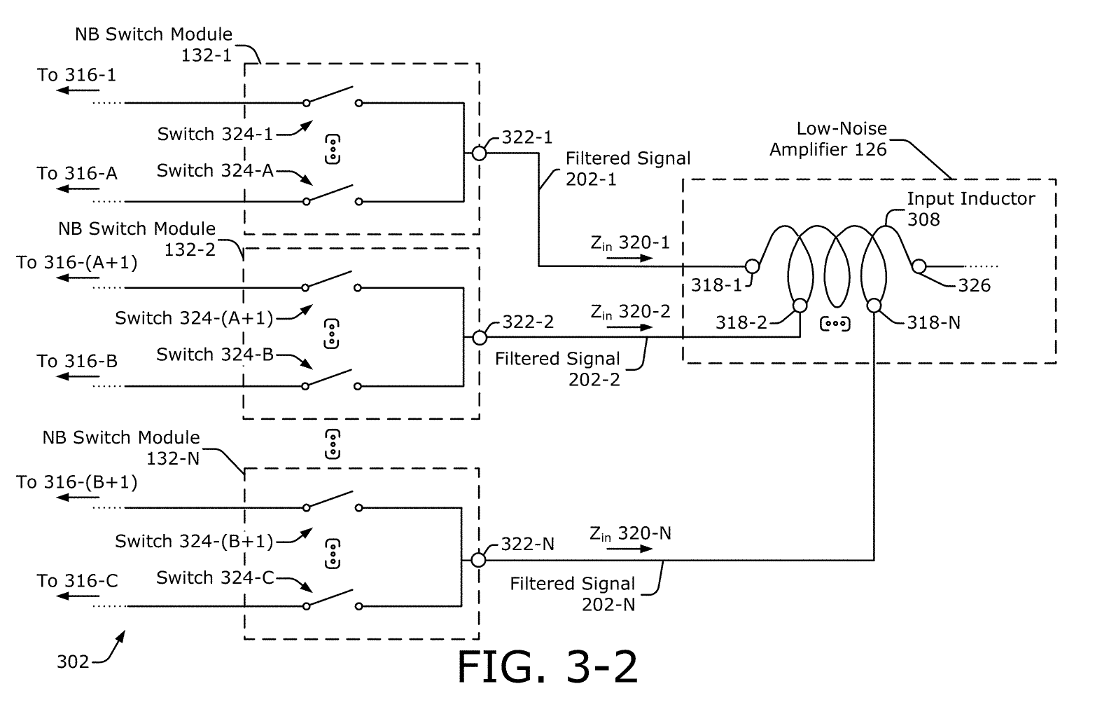

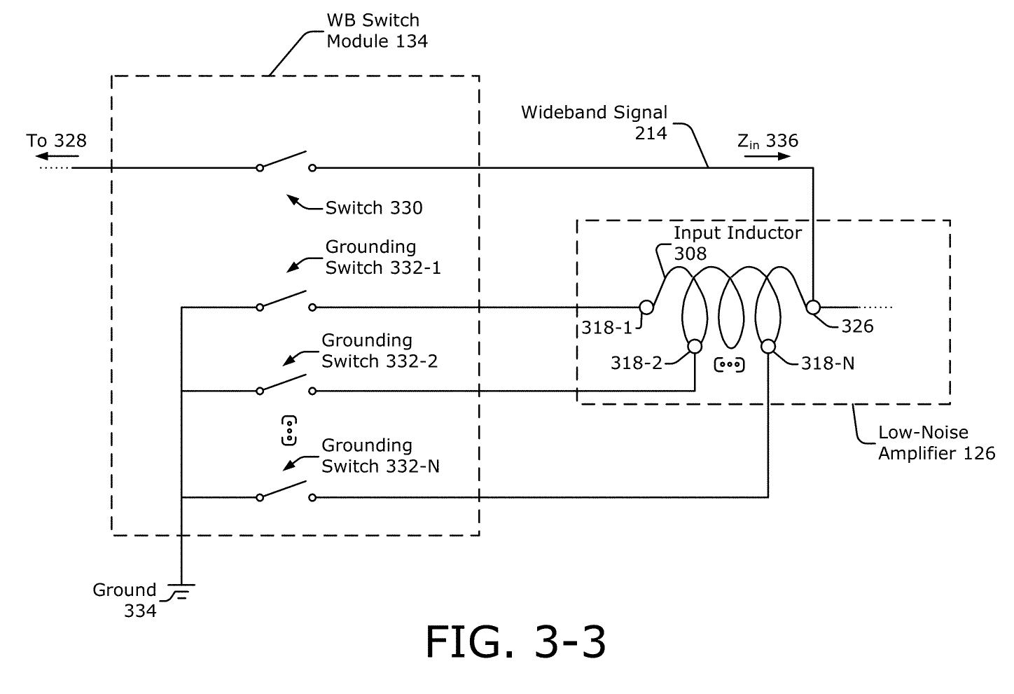

The narrowband switch module 132 includes at least one switch that connects or disconnects the band-pass filter 122 to or from the low-noise amplifier 126. In this manner, the narrowband switch module 132 provides a narrowband signal to an input of the low-noise amplifier 126. As used herein, the term “connect” or “connected” refers to an electrical connection, including a direct connection (e.g., connecting discrete circuit elements via a same node) or an indirect connection (e.g., connecting discrete circuit elements via one or more other devices or other discrete circuit elements). Assuming there are multiple band-pass filters 122, the narrowband switch module 132 can include multiple switches that respectively connect, one at a time, each of the multiple band-pass filters 122 to the low-noise amplifier 126. In general, the narrowband switch module 132 enables the filtered signal that is produced by the connected band-pass filter 122 to be received by the low-noise amplifier 126. The narrowband switch module 132 is further described with respect to FIG. 3-2.

The wideband switch module 134 includes two or more switches. One of the switches bypasses the band-pass filter 122 to connect a node of the wireless transceiver 120 to or from the low-noise amplifier 126. In this manner, the wideband switch module 134 provides a wideband signal to an input of the low-noise amplifier 126. Another one of the switches connects the low-noise amplifier 126 to a ground. Together, the two or more switches enable the low-noise amplifier 126 to operate in the common-gate configuration. The wideband switch module 134 is further described with respect to FIG. 3-3.

The low-noise amplifier 126, which is described with reference to FIGS. 2-6, can at least partially implement gain-dependent impedance matching and linearity. The low-noise amplifier 126 and the controller 128 are further described with respect to FIG. 2.

FIG. 2 illustrates a portion of the wireless transceiver 120 for gain-dependent impedance matching and linearity. In the depicted configuration, a receiver chain of the wireless transceiver 120 includes one or more band-pass filters 122-1 to 122-A associated with a frequency band range 200-1, one or more band-pass filters 122-(A+1) to 122-B associated with a frequency band range 200-2, and one or more band-pass filters 122-(B+1) to 122-C associated with a frequency band range 200-N. The receive chain also includes a node 210 associated with a frequency band range 212, multiple narrowband switch modules 132-1, 132-2 . . . 132-N, the wideband switch module 134, and the low-noise amplifier 126. In some implementations, the frequency band range 212 includes at least a portion of the frequency band ranges 200-1 to 200-N. In this example, A, B, C, and N represent positive integers. Thus, more or fewer than three narrowband switch modules or frequency bands can alternatively be implemented. The wireless transceiver 120 also includes the controller 128.

As shown in FIG. 2, each of the narrowband switch modules 132-1, 132-2, and 132-N is connected to a different group of band-pass filters associated with a different frequency band range 200-1, 200-2, and 200-N, respectively. Output nodes of the narrowband switch modules 132-1 to 132-N are connected to a different input node of the low-noise amplifier 126, as further described with respect to FIG. 3-2. In other implementations, the multiple narrowband switch modules 132-1 to 132-N can be implemented as a single switch module with multiple outputs. As an example, the multiple narrowband switch modules 132-1 to 132-N can be implemented with at least one multiplexer.

Each of the multiple band-pass filters 122-1 to 122-A, 122-(A+1) to 122-B, and 122-(B+1) to 122-C passes a different frequency band that is within the corresponding frequency band range 200-1 to 200-N. For example, each of the band-pass filters 122-1 to 122-A can pass signals within one of the frequency bands 1, 3, or 66. These example frequency bands are within a middle frequency band range that includes frequencies between approximately 1.4 and 2.2 gigahertz (GHz). Likewise, each of the band-pass filters 122-(A+1) to 122-B can pass signals within one of the frequency bands 7, 30, 40, or 41, which are within a high frequency band range that includes frequencies between approximately 2.3 to 2.7 GHz. The band-pass filters 122(B+1) to 122-C can each pass signals within one of the frequency bands 42, 43, or 48, which are within an ultra-high frequency band that includes frequencies between approximately 3.4 and 3.8 GHz. Although not shown, the band-pass filters 122-1 to 122-C can be connected to other components of the wireless transceiver 120, such as the antenna 130 or the node 210.

Together the narrowband switch modules 132-1 to 132-N select one of the multiple band-pass filters 122-1 to 122-C for providing a filtered signal 202-1 to 202-N to the low-noise amplifier 126. In other words, the narrowband switch modules 132-1 to 132-N connect one of the band-pass filters 122-1 to 122-C to the low-noise amplifier 126 at a time and disconnects the other band-pass filters. If selected band-pass filter is associated with the frequency band range 200-1, the narrowband switch module 132-1 passes the filtered signal 202-1 from the selected band-pass filter to the low-noise amplifier 126. Alternatively, if the selected band-pass filter is associated with the frequency band range 200-2 or 200-N, the narrowband switch modules 132-2 and 132-N respectively pass the filtered signal 202-2 or 202-N from the selected band-pass filter to the low-noise amplifier 126.

The wideband switch module 134 is connected between the node 210 and the low-noise amplifier 126. The wideband switch module 134 passes a wideband signal 214 associated with the frequency band range 212 from the node 210 to the low-noise amplifier 126. As an example, the wideband signal 214 can include component signals respectively associated with multiple narrow frequency bands, such as the frequency bands 1 and 7.

In some cases, the narrowband switch modules 132-1 to 132-N and the wideband switch module 134 can receive from the controller 128 a switch control signal 204, which specifies a configuration of multiple switches (not shown in FIG. 2) within the narrowband switch modules 132-1 to 132-N and the wideband switch module 134. In some aspects, the switch control signal 204 can comprise a multi-bit signal with each bit controlling a state of a switch within the multiple narrowband switch modules 132-1 to 132-N and the wideband switch module 134. Using the switch control signal 204, the controller 128 selectively enables one of the narrowband switch modules 132-1 to 132-N to provide one of the filtered signals 202-1 to 202-N as an input signal 216 to the low-noise amplifier 126 or the wideband switch module 134 to provide the wideband signal 214 as the input signal 216 to the low-noise amplifier 126.

The low-noise amplifier 126 amplifies the input signal 216 that is received to produce an amplified signal 206. In some cases, the low-noise amplifier 126 can receive from the controller 128 a gain control signal 208, which specifies a target amount of amplification of the input signal 216. An output of the low-noise amplifier 126 can be connected to other components of the wireless transceiver 120, such as other amplifiers or mixers, until a received signal is provided to a baseband modem (not shown) for further processing.

The controller 128 includes control circuitry to generate the switch control signal 204 and the gain control signal 208. The controller 128 can use a communication interface, such as a serial bus, to route the switch control signal 204 to both the narrowband switch modules 132-1 to 132-N and the wideband switch module 134, and route the gain control signal 208 to the low-noise amplifier 126. In some aspects, the mobile industry processor interface (MIPI) radio-frequency front-end (RFFE) interface standard may be used for communicating these control signals. One or more registers may also be used to store and provide access to information that is carried by the switch control signal 204 or the gain control signal 208. The controller 128, for example, can write to the register upon startup or during operation of the wireless transceiver 120.

The controller 128 may also be responsible for setting an operational mode of the wireless transceiver 120. The operational mode can be associated with a communication frequency band the wireless transceiver 120 may receive or a gain mode of the wireless transceiver 120. In this way, the controller 128 can determine the appropriate information to convey in the switch control signal 204 or the gain control signal 208 based on the current operational mode. In other cases, the controller 128 may reference information that is stored in the computer-readable storage medium 110 for generating the switch control signal 204 or the gain control signal 208.

To specify the switch configuration of the narrowband switch modules 132-1 to 132-N and the wideband switch module 134, the controller 128 can determine a frequency band of a wireless communication signal that the wireless transceiver 120 may receive. For example, if the wireless communication signal is within a frequency band associated with a passband of the band-pass filter 122-1, the controller 128 can generate the switch control signal 204 to cause the narrowband switch module 132-1 to connect the band-pass filter 122-1 to the low-noise amplifier 126. The switch control signal 204 can also cause the other narrowband switch modules 132-2 to 132-N to disconnect the other band-pass filters from the low-noise amplifier 126 and the wideband switch module 134 to disconnect the node 210 from the low-noise amplifier 126. In another example, if the wireless communication signal encompasses multiple frequency bands associated with passbands of two or more band-pass filters 122-1 to 122-C, the controller 128 can generate the switch control signal 204 to cause the wideband switch module 134 to connect the node 210 to the low-noise amplifier 126. In this case, the switch control signal 204 can also cause the narrowband switch modules 132-1 to 132-N to disconnect the band-pass filters 122-1 to 122-C from the low-noise amplifier 126.

The controller 128 can determine a target amplification of the wireless communication signal or a target power mode of the computing device 102 for performing the wireless communication. This determination may be based on information provided by the processor 108, such as a measured distance between the base station 104 and the computing device 102, predetermined communication performance, available power of the computing device 102 (e.g., remaining battery power), and so forth. Accordingly, the controller 128 can use this information to specify a gain of the low-noise amplifier 126, as described in further detail with respect to FIG. 4. In some implementations, the narrowband switch modules 132-1 to 132-N, the wideband switch module 134, and the low-noise amplifier 126 are implemented on a same integrated circuit, as shown in FIG. 3-1.

FIG. 3-1 illustrates an example implementation of the wireless transceiver 120 for gain-dependent impedance matching and linearity. The wireless transceiver 120 includes an integrated circuit 302 implemented on an amplifier die 304. The integrated circuit 302 includes the switch modules 124-1 to 124-(N+1) and the low-noise amplifier 126. The switch modules 124-1 to 124-(N+1) are respectively implemented as the narrowband switch modules 132-1 to 132-N and the wideband switch module 134. The low-noise amplifier 126 also includes an impedance-matching circuit 306, which includes at least one input inductor 308 and at least two degeneration inductors 310-1 to 310-P, which are depicted individually in FIG. 4. The input inductor 308 and the degeneration inductors 310-1 to 310-P can be implemented on one or more metal layers of the integrated circuit 302. The input inductor 308 and the degeneration inductors 310-1 to 310-P are magnetically coupled together, as described in further detail with respect to FIG. 4.

The integrated circuit 302 can be mounted to a substrate 312, which includes an interface 314, multiple input terminals 316-1 to 316-C, an input terminal 328, the multiple band-pass filters 122-1 to 122-C (of FIG. 2), and the node 210 (of FIG. 2). As shown in FIG. 3-1, the multiple band-pass filters 122-1 to 122-C can be separate from the integrated circuit 302. The interface 314, which is disposed on a surface of the substrate 312, is configured to accept and connect to the amplifier die 304. The multiple input terminals 316-1 to 316-C respectively connect the multiple band-pass filters 122-1 to 122-C to one of the narrowband switch modules 132-1 to 132-N, as further shown in FIG. 3-2. The input terminal 328 connects the node 210 to the wideband switch module 134, as further shown in FIG. 3-3.

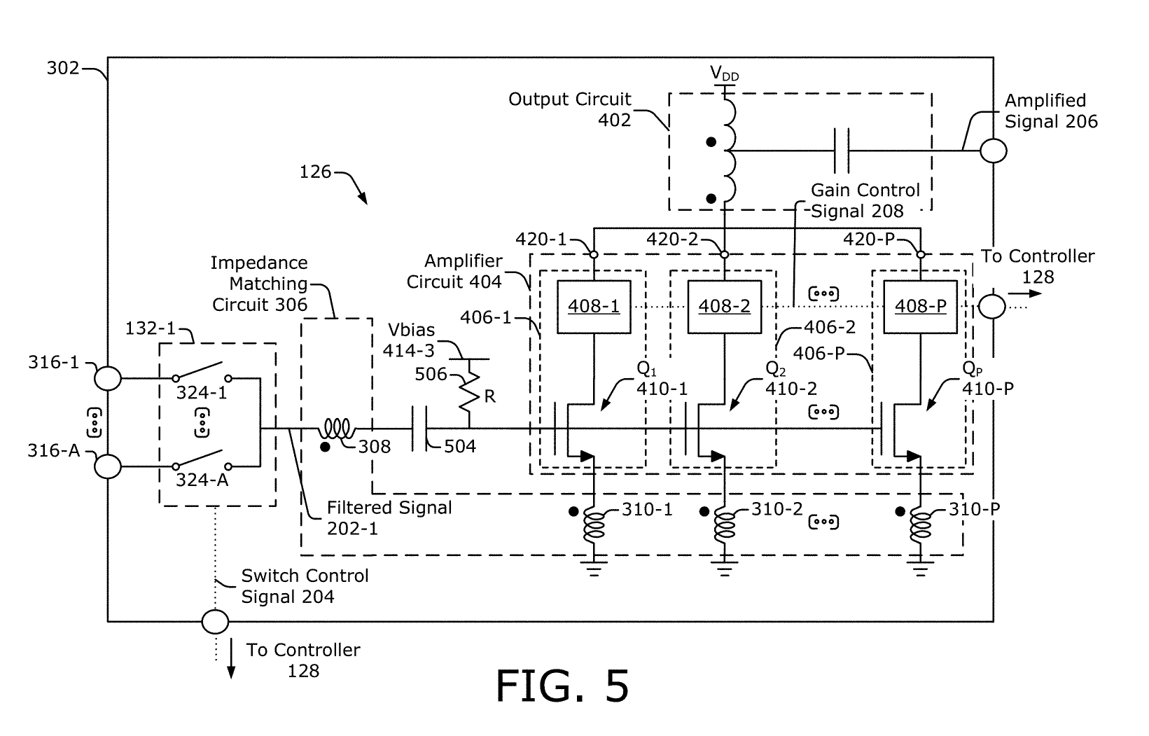

Although not explicitly shown, the interface 314 can include additional terminals. Additional terminals can be used, for example, to communicate the switch control signal 204 or the gain control signal 208 that is generated by the controller 128 or to provide the amplified signal 206 to other components of the wireless transceiver 120. Also, a matching set of input terminals 316-1 to 316-C and 328 can be implemented on the integrated circuit 302, a portion of which are shown in FIG. 5. Connections between the narrowband switch modules 132-1 to 132-N and the input inductor 308 within the integrated circuit 302 are further described with respect to FIG. 3-2.

FIG. 3-2 illustrates example connections between the narrowband switch modules 132-1 to 132-N and the input inductor 308 for gain-dependent impedance matching and linearity. In the depicted configuration, the input inductor 308 includes multiple input nodes 318-1, 318-2 . . . 318-N and an output node 326. The multiple input nodes 318-1 to 318-N can be different taps on the input inductor 308. The output node 326 can be connected to other components within the low-noise amplifier 126, as shown in FIGS. 4 and 5.

Consider, by way of example, that the input inductor 308 comprises a conductor that has at least one loop formed about a center axis. The loop represents a coil or winding of the input inductor 308 and can be shaped in the form of an oval or a polygon (e.g., a rectangle or an octagon). In some cases, the conductor can have a spiral shape with multiple loops curving in a gradually lengthening or shortening radius about the center axis. The multiple input nodes 318-1 to 318-N are connected to the conductor at different points along the one or more loops. As such, an effective length of the conductor differs as seen from each of the multiple input nodes 318-1 to 318-N to the output node 326.

Generally, the multiple input nodes 318-1 to 318-N are connected to or positioned at different locations along a length of the input inductor 308. Consequently, an input impedance of the low-noise amplifier 126 differs across the multiple input nodes 318-1 to 318-N. In this example, the low-noise amplifier 126 has input impedances (Zin) 320-1, 320-2, and 320-N at the input nodes 318-1, 318-2, and 318-N, respectively. An observed inductance of the input inductor 308 also differs across the multiple input nodes 318-1 to 318-N. The inductance of the input inductor 308 is based on a portion of the input inductor 308 that a signal accepted at the input node 318-1 to 318-N propagates through. In this case, the inductance of the input inductor 308 decreases across the input nodes 318-1 to 318-N such that a location of the input node 318-1 causes the input inductor 308 to present a relatively large inductance and a location of the input node 318-N causes the input inductor 308 to present a relatively small inductance.

Output nodes 322-1, 322-2, and 322-N of the narrowband switch modules 132-1, 132-2, and 132-N are respectively connected to the input nodes 318-1, 318-2, and 318-N. Each of the narrowband switch modules 132-1 to 132-N include at least one switch. For example, the narrowband switch module 132-1 includes switches 324-1 to 324-A, which are respectively connected to the band-pass filters 122-1 to 122-A of FIG. 2 via the input terminals 316-1 to 316-A. The switches 324-1 to 324-A are also connected to the input node 318-1 via the output node 322-1. Similarly, the narrowband switch module 132-2 includes switches 324-(A+1) to 324-B, which are respectively connected to the band-pass filters 122-(A+1) to 122-B of FIG. 2 via the input terminals 316-(A+1) to 316-B and are connected to the input node 318-2 via the output node 322-2. The narrowband switch module 132-N includes switches 324-(B+1) to 324-C, which are respectively connected to the band-pass filters 122-(B+1) to 122-C of FIG. 2 via the input terminals 316-(B+1) to 316-C and are connected to the input node 318-N via the output node 322-N.

In this manner, the narrowband switch modules 132-1 to 132-N can connect different band-pass filters 122-1 to 122-C associated with different frequency band ranges 200-1 to 200-N to different input nodes 318-1 to 318-N of the input inductor 308 to cause the input inductor 308 to present different inductances and the low-noise amplifier 126 to therefore present different input impedances 320-1 to 320-N. As such, both the input impedance 320-1 to 320-N of the low-noise amplifier 126 and the inductance of the input inductor 308 can be increased for frequency band ranges 200-1 to 200-N that have lower frequencies relative to frequency band ranges 200-1 to 200-N that have higher frequencies. The variety of different input impedances 320-1 to 320-N and inductances of the input inductor 308 enable the low-noise amplifier 126 to provide gain-dependent impedance matching and linearity for filtered signals 202-1 to 202-N having substantially different frequencies (e.g., for filtered signals 202-1 to 202-N associated with different frequency band ranges 200-1 to 200-N), as further described with respect to FIG. 4.

During a narrowband operational mode, the input inductor 308 selectively accepts the input signal 216 (of FIG. 2) at one of the input nodes 318-1 to 318-N and propagates the input signal 216 to the output node 326. The operation of the input inductor 308 during a wideband mode is further described with respect to FIG. 3-3.

FIG. 3-3 illustrates example connections between the wideband switch module 134 and the input inductor 308 for gain-dependent impedance matching and linearity. In the depicted configuration, the wideband switch module 134 includes a switch 330, which is connected between the input terminal 328 and the output node 326 of the input inductor 308. The wideband switch module 134 also includes at least one grounding switch 332-1, 332-2 . . . 332-N, which is connected between the input inductor 308 and a ground 334. In this example, the grounding switches 332-1 to 332-N are respectively connected between the input nodes 318-1 to 318-N of the input inductor 308 and the ground 334. Together, the grounding switches 332-1 to 332-N selectively connect one of the input nodes 318-1 to 318-N to the ground 334 at a time.

In this example, the low-noise amplifier 126 has an input impedance (Zin) 336 at the output node 326, which can vary depending on which one of the grounding switches 332-1 to 332-N is closed. An observed inductance of the input inductor 308 also differs depending on which one of the grounding switches 332-1 to 332-N is closed. The observed inductance of the input inductor 308 is based on a portion of the input inductor 308 that the wideband signal 214, which is accepted at the output node 326, propagates through. Similar to FIG. 3-2, the inductance of the input inductor 308 decreases across the input nodes 318-1 to 318-N such that a location of the input node 318-1 causes the input inductor 308 to present a relatively large inductance and a location of the input node 318-N causes the input inductor 308 to present a relatively small inductance.

During a wideband operational mode, the input inductor 308 accepts the wideband signal 214 at the output node 326 and propagates the wideband signal 214 to one of the input nodes 318-1 to 318-N, and then to the ground 334. In this manner, the input signal 216 propagates in a different direction through the input inductor 308 relative to the narrowband operational mode described with respect to FIG. 3-2. In other words, the output node 326 operates as an input node and one of the input nodes 318-1 to 318-N operates as an output node during the wideband operational mode.

FIG. 4 illustrates an example low-noise amplifier 126 for gain-dependent impedance matching and linearity. The low-noise amplifier 126 includes an output circuit 402, an amplifier circuit 404, and the impedance-matching circuit 306. The output circuit 402 may be connected to an output terminal (not shown). In addition to providing the amplified signal 206 at the output terminal, the output circuit 402 provides output impedance matching by transforming an output impedance of the low-noise amplifier 126 to a predetermined value, such as 50 ohms. The output circuit 402 can be implemented, for example, using a transformer, a choke, an autotransformer, and so forth. The low-noise amplifier 126 accepts the input signal 216. In some situations, the input signal 216 comprises one of the filtered signal 202-1 to 202-N accepted at one of the input nodes 318-1 to 318-N (e.g., of FIG. 3-2). In other situations, the input signal 216 comprises the wideband signal 214 accepted the output node 326 (e.g., of FIG. 3-3). The input signal 216 passes through at least a portion of the input inductor 308 of the impedance-matching circuit 306 to the amplifier circuit 404 based on a location of the input node 318-1 to 318-N.

The amplifier circuit 404 includes at least two amplifier branches 406, which forms at least part of the low-noise amplifier 126. An amplifier branch 406 includes an input stage and a cascode stage 408. The input stage can be implemented using an input transistor 410, such as an n-channel metal-oxide semiconductor field-effect transistor (MOSFET) that is configured as a common-source amplifier. In the depicted configuration, the input transistor 410 has a gate connected to the input inductor 308, a source connected to one of the degeneration inductors 310, and a drain connected to the cascode stage 408.

The cascode stage 408 is connected between the drain of the input transistor 410 and the output circuit 402. The cascode stage 408 can be implemented using, for example, another amplifier that includes one or more other transistors. In some implementations, the cascode stage 408 includes multiple cascode stages. An example double cascode configuration includes a first cascode transistor Q_{L1} 412-1 and a second cascode transistor Q_{L2} 412-2, both of which are configured as common-gate amplifiers. Within each amplifier branch 406, the first cascode transistor 412-1 and the second cascode transistor 412-2 are connected in series with the input transistor 410. Assuming the cascode stage 408 is implemented using the double cascode configuration described above, the controller 128 (not shown) can adjust bias voltages 414, such as VBias₁ 414-1 and VBias₂ 414-2, via the gain control signal 208 for the first and second cascode transistors 412-1 and 412-2, respectively. Using the bias voltages 414, the controller 128 can enable or disable different combinations of the amplifier branches 406.

In the depicted configuration, the amplifier circuit 404 includes P amplifier branches 406-1 to 406-P. This includes a first amplifier branch 406-1, a second amplifier branch 406-2, and a Pth amplifier branch 406-P, with P representing a positive integer. Each amplifier branch 406-1 to 406-P includes a node 420, such as nodes 420-1, 420-2, and 420-P that are respectively associated with the amplifier branches 406-1, 406-2, and 406-P. The nodes 420-1 to 420-P of the amplifier branches 406-1 to 406-P are connected together and coupled to the output circuit 402. In this way, the amplifier branches 406-1 to 406-P are connected in parallel between the output circuit 402 and a ground 416.

By enabling or disabling different combinations of the amplifier branches 406-1 to 406-P, the controller 128 enables the amplifier circuit 404 to provide different gains. For example, the controller 128 may enable one of the amplifier branches 406-1 to 406-P for a lower gain mode or enable two or more of the amplifier branches 406-1 to 406-P for a higher gain mode. In general, higher gains are achieved by enabling more amplifier branches 406-1 to 406-P and lower gains are achieved by enabling fewer amplifier branches 406-1 to 406-P.

The impedance-matching circuit 306 includes the input inductor 308 having an inductance of L_{Input}, which can change based on a portion of the input inductor 308 that the input signal 216 propagates through. At least a portion of the input inductor 308 is connected between the one of the switch modules 124-1 to 124-(N+1) and the respective gates of the input transistors 410 of the amplifier branches 406-1 to 406-P. The impedance-matching circuit 306 also includes at least two degeneration inductors 310 connected between respective sources of the input transistors 410 of the amplifier branches 406-1 to 406-P and the ground 416. In the depicted configuration, P degeneration inductors 310-1 to 310-P are shown, including a first degeneration inductor 310-1, a second degeneration inductor 310-2, and a Pth degeneration inductor 310-P. Each of the degeneration inductors 310-1 to 310-P has an inductance, such as respective inductances L₁, L₂, and L_{P} for the first degeneration inductor 310-1, the second degeneration inductor 310-2, and the Pth degeneration inductor 310-P. Generally, a quantity of degeneration inductors 310-1 to 310-P equals a quantity of amplifier branches 406-1 to 406-P; however, different numbers may be implemented. For example, one of the degeneration inductors 310-1 to 310-P can be connected to two or more of the amplifier branches 406-1 to 406-P.

The input inductor 308 and the degeneration inductors 310-1 to 310-P are magnetically coupled and generate a mutual inductance. As illustrated using the dot convention, a current that flows through one of the degeneration inductor 310-1 to 310-P from the source of an input transistor 410 to the ground 416 induces, via a generated magnetic field, a portion of another current in the input inductor 308 that flows from one of the input nodes 318-1 to 318-N of the input inductor 308 to an output node of the input inductor 308 that is connected to the amplifier circuit 404. Additionally, as shown with respect to Equations 1 and 4 below, this magnetic coupling enables a real-part of an input impedance 320-1 to 320-N and 336 of the low-noise amplifier 126 to be dependent upon a summation of the inductances of the degeneration inductors 310-1 to 310-P and a mutual inductance between the input inductor 308 and the degeneration inductors 310-1 to 310-P.

During operation, if the input signal 216 is provided by one of the narrowband switch modules 132-1 to 132-N, the low-noise amplifier 126 operates in the common-source configuration as the input signal 216 propagates from one of the input nodes 318-1 to 318-N to the output node 326. In this case, a larger portion of the input signal 216 is provided at the gates of the input transistors 410 relative to other portions of the input signal 216 that are provided to respective sources of the input transistors 410 via the magnetic coupling between the input inductor 308 and the degeneration inductors 310-1 to 310-P (as represented by coupling coefficients K₁, K₂, and K_{P}). Alternatively, if the input signal 216 is provided by the wideband switch module 134, the low-noise amplifier 126 operates in the common-gate configuration with gm-boosting as the input signal 216 propagates from the output node 326 to one of the input nodes 318-1 to 318-N to ground. In this case, larger portions of the input signal 216 are provided at respective sources of the input transistors 410 via the magnetic coupling relative to the portions of the input signal 216 that are provided at the gates of the input transistors 410.

In addition to each of the degeneration inductors 310-1 to 310-P being magnetically coupled to the input inductor 308, the degeneration inductors 310-1 to 310-P are also magnetically coupled with each other (represented by coupling coefficients K₁₂, K_{1P}, and K_{2P}). As shown using the dot-convention, a first current that flows through the first degeneration inductor 310-1 from the source of the input transistor 410 to the ground 416 induces a portion of a second current in the second degeneration inductor 310-2 that flows from the source of another input transistor 410 of the second amplifier branch 406-2 to the ground.

Generally, the impedance-matching circuit 306 is used to adjust the input impedances 320-1 to 320-N and 336 of the low-noise amplifier 126 to a predetermined value, such as 50 ohms. In the common-gate configuration, the input impedance (Zin) 336 of the low-noise amplifier 126 is related to the effective transconductance (gm) of the amplifier circuit 404 by Equation 1 below.

$$Zin ∝ \frac{{n}^{2}}{gm ( 1 + n )} \qquad Equation 1$$

where n is related to the inductances of the input inductor 308 and the degeneration inductors 310-1 to 310-P, as shown by Equation 2 below.

$$N = \sqrt{\frac{{L}_{Input}}{{L}_{T}}} \qquad Equation 2$$

where L_{Input} represents the inductance of the input inductor 308, which can change depending on a portion of the input inductor 308 that the input signal 216 propagates through. The total inductance of the degeneration inductors 310-1 to 310-P (e.g., the total degeneration inductance) is represented by L_{T}, which is shown by Equation 3 below.

L_{T}=(L₁+M₁₂+ . . . +M_{1P})∥(L₂+M₂₁+ . . . +M_{2P})∥ . . . ∥(L_{P}+M_{P1}+ . . . +M_{P(P-1)}) Equation 3

where Mᵢⱼ is the mutual inductance between the ith degeneration inductor 310 and the jth degeneration inductor 310.

In the common-source configuration, the resulting real-part of the input impedance 320-1 to 320-N(Re(Zin)) of the low-noise amplifier 126 is approximated by Equation 4 below.

$$Re ( Zin ) = \frac{{\sum }_{i = 1}^{P} {G}_{mi}}{{\sum }_{i = 1}^{P} {C}_{gsi}} ( {L}_{T} + \frac{K}{n} {L}_{Input} ) \qquad Equation 4$$

where i represents individual amplifier branches 406, Gₘᵢ is the transconductance for the ith amplifier branch 406, C_{gsi} is the capacitance seen from the gate to the source of the ith input transistor 410, and K is a coupling coefficient that has a value between zero and one. In this case, K=K₁=K₂=K_{P} for simplicity. Although the coupling coefficients between the input inductor 308 and respective degeneration inductors 310-1 to 310-P are shown to be similar in the above equation for simplicity, the values of the coupling coefficients can be respectively different.

As seen in Equations 1 and 4 above, a predetermined value of the input impedance 320-1 to 320-N and 336 can be achieved from the inductances of the input inductor 308 and the degeneration inductors 310-1 to 310-P as well as the coupling coefficients. Accordingly, the impedance-matching circuit 306 provides a portion of the input impedance 320-1 to 320-N and 336 for the low-noise amplifier 126 such that the input impedance 320-1 to 320-N and 336 substantially matches an output impedance of a connected band-pass filter 122-1 to 122-C (of FIG. 2) or an output impedance at the node 210. For example, the input impedance 320-1 to 320-N of the low-noise amplifier 126 may be substantially conjugately matched to the respective output impedance of the band-pass filter 122-1 to 122-C such that a reflection coefficient at the input terminal 316-1 to 316-C (e.g., scattering parameter S11) is less than negative ten decibels. Similarly, the input impedance 336 of the low-noise amplifier 126 may be substantially conjugately matched to the respective output impedance at the node 210 such that a reflection coefficient at the input terminal 328 is less than negative ten decibels.

The use of multiple degeneration inductors 310-1 to 310-P improves input impedance matching for different gain modes. At a lower gain mode, the controller 128 may, for example, enable the first amplifier branch 406-1 and disable the other amplifier branches (e.g., 406-2 to 406-P). This enables a current to flow through the first amplifier branch 406-1 and the first degeneration inductor 310-1 and substantially prevents other currents from flowing through the other amplifier branches (e.g., 406-2 to 406-P) and the other degeneration inductors (e.g., 310-2 to 310-P). Because the degeneration inductors 310-1 to 310-P are effectively connected in parallel between the ground 416 and the output circuit 402, disabling one or more of the parallel paths via the amplifier branches 406-2 to 406-P causes the total degeneration inductance to increase from a parallel combination of the multiple degeneration inductors 310-1 to 310-P to the inductance of the first degeneration inductor 310-1. Thus, considering Equation 4, the transconductance summation decreases (e.g., Gₘ₁+Gₘ₂+ . . . +Gₘₚ→Gₘ₁) and the total degeneration inductance increases (e.g., L_{T}=L₁). The resulting increase in L_{T} compensates for at least a portion of the decrease in the transconductance summation, thereby improving input impedance matching for lower gain modes.

Due to this compensation, similar impedance matching performance can be realized for different gains. As an example, if the gain of the low-noise amplifier 126 changes by approximately six decibels, the reflection coefficient at the connected input terminal 316-1 to 316-C or 328 may change by less than one decibel. As another example, if the gain of the low-noise amplifier 126 changes by approximately twelve decibels, the reflection coefficient at the connected input terminal 316-1 to 316-C or 318 may change by less than three decibels. In this way, the low-noise amplifier 126 can maintain similar input impedance matching performance across a variety of different gains.

The multiple degeneration inductors 310-1 to 310-P also improve linearity for lower gain modes. In general, transconductance changes based on the input signal 216, which contributes to a portion of non-linearity in the amplifier circuit 404. In contrast, the degeneration inductances (L₁, L₂, and L_{P}) do not depend on the input signal 216. As transconductance decreases and the total degeneration inductance increases, a gain of the low-noise amplifier 126 becomes more dependent upon the total degeneration inductance than the transconductance. Consequently, the gain depends less on the input signal 216, which increases linearity of the low-noise amplifier 126 for lower gain modes. The linearity can improve for lower gain modes, for example, by approximately four decibels or more, as compared to other low-noise amplifiers 126 that have a single degeneration inductor 310.

The input impedance matching provided by the impedance-matching circuit 306 also accommodates for wideband operation, meaning that input impedance matching can be provided across a wide range of frequencies (across one or more of the frequency band ranges 200-1 to 200-N or across the frequency band range 212). In some implementations of the amplifier circuit 404, at least one tuning capacitor (not shown) can be connected between the gate and the source of one or more of the input transistors 410. This tuning capacitor can be implemented as a programmable capacitor with an adjustable capacitance that can be used to further adjust the input impedance 320 for different frequency bands. With respect to Equation 4, the tuning capacitor adds an additional capacitance to the gate-to-source capacitance. However, due to the wideband input impedance-matching performance of the impedance-matching circuit 306, the tuning capacitor becomes optional and can be removed to further save space on the integrated circuit 302.

In the common-source configuration, the impedance-matching circuit 306 can also set an imaginary-part of the input impedance 320-1 to 320-N (Im(Zin)) of the low-noise amplifier 126 to achieve a target input matching and noise figure performance, as shown in Equation 5 below for the common-source configuration.

$$Im ( Zin ) = ω ( {L}_{T} ( 1 + K \cdot n ) + {L}_{Input} ( 1 + \frac{K}{n} ) - \frac{1}{{ω}^{2} {\sum }_{i = 1}^{P} {C}_{gsi}} ) \qquad Equation 5$$

where ω represents an angular frequency.

As seen in Equation 5, the inductances of the input inductor 308 and the degeneration inductors 310-1 to 310-P, as well as the coupling coefficients, can be determined to achieve a target value of the imaginary part of the input impedance 320-1 to 320-N. In some implementations, the impedance-matching circuit 306 can set the input impedance 320-1 to 320-N to a value that is desirable for both input impedance matching and noise matching.

Compared to off-chip matching circuits, the impedance-matching circuit 306 is implemented on the integrated circuit 302, which saves space on the integrated circuit 302 and can enable a size of the integrated circuit 302 to be decreased. The space saving occurs because bumps and electro-static discharge (ESD) protection circuits are no longer needed on the integrated circuit 302 and can be removed. The ESD protection circuits can also add significant capacitance between the input terminals 316-1 to 316-C, the input terminal 328, and the ground 416. Removing the ESD protection circuits can therefore improve the noise figure of the amplifier circuit 404. Furthermore, the impedance-matching circuit 306 can have finer resolution than discrete components that are used for external impedance matching. This provides additional flexibility and control for optimizing the impedance matching and noise figure performance during the design phase.

FIG. 5 illustrates an example integrated circuit 302 for gain-dependent impedance matching and linearity. The integrated circuit 302 includes the narrowband switch modules 132-1 and the low-noise amplifier 126. Other implementations can include more than one narrowband switch module 132 and/or the wideband switch module 134. The narrowband switch module 132-1 includes multiple switches 324-1 to 324-A, which are respectively connected between the multiple input terminals 316-1 to 316-A and the impedance-matching circuit 306. The narrowband switch module 132-1 connects, via the multiple switches 324-1 to 324-A, one of multiple input terminals 316-1 to 316-A at a time to the impedance-matching circuit 306. The narrowband switch module 132-1 can receive the switch control signal 204 from the controller 128 to determine a configuration of the multiple switches 324-1 to 324-A. For example, the narrowband switch module 132-1 can close, based on the switch control signal 204, a first switch 324-1 to connect the first input terminal 316-1 to the impedance-matching circuit 306. As described above with respect to FIG. 3-2, the narrowband switch module 132-1 provides, to the low-noise amplifier 126, the filtered signal 202-1 from one of the band-pass filters 122-1 to 122-A via one of the multiple input terminals 316-1 to 316-A.

The low-noise amplifier 126 includes the output circuit 402, which is implemented using an autotransformer in FIG. 5. The output circuit 402 provides the amplified signal 206 that is generated via the amplifier circuit 404 to other components of the wireless transceiver 120. Additionally, the low-noise amplifier 126 includes a decoupling capacitor 504 connected between the input inductor 308 and the amplifier circuit 404. Furthermore, a bias resistor 506 having a resistance R can be connected between another bias voltage 414-3 (VBias 414-3) and a node located between the decoupling capacitor 504 and the amplifier circuit 404. The other bias voltage 414-3 may be different than the bias voltages applied to the cascode stages 408 (e.g., bias voltages 414-1 and 414-2 in FIG. 4).

In the depicted configuration, the amplifier circuit 404 includes the amplifier branches 406-1 to 406-P (of FIG. 4). The first amplifier branch 406-1 includes a first input transistor Q₁ 410-1 and a first cascode stage 408-1, the second amplifier branch 406-2 includes a second input transistor Q₂ 410-2 and a second cascode stage 408-2, and a Pth amplifier branch 406-P includes a Pth input transistor Q_{P} 410-P and a Pth cascode stage 408-P. By enabling or disabling different combinations of the amplifier branches 406-1 to 406-P via the gain control signal 208, the controller 128 enables the amplifier circuit 404 to provide different gains. For example, the controller 128 may enable one of the amplifier branches 406-1 to 406-P for a lower gain mode or enable two or more of the amplifier branches 406-1 to 406-P for a higher gain mode.

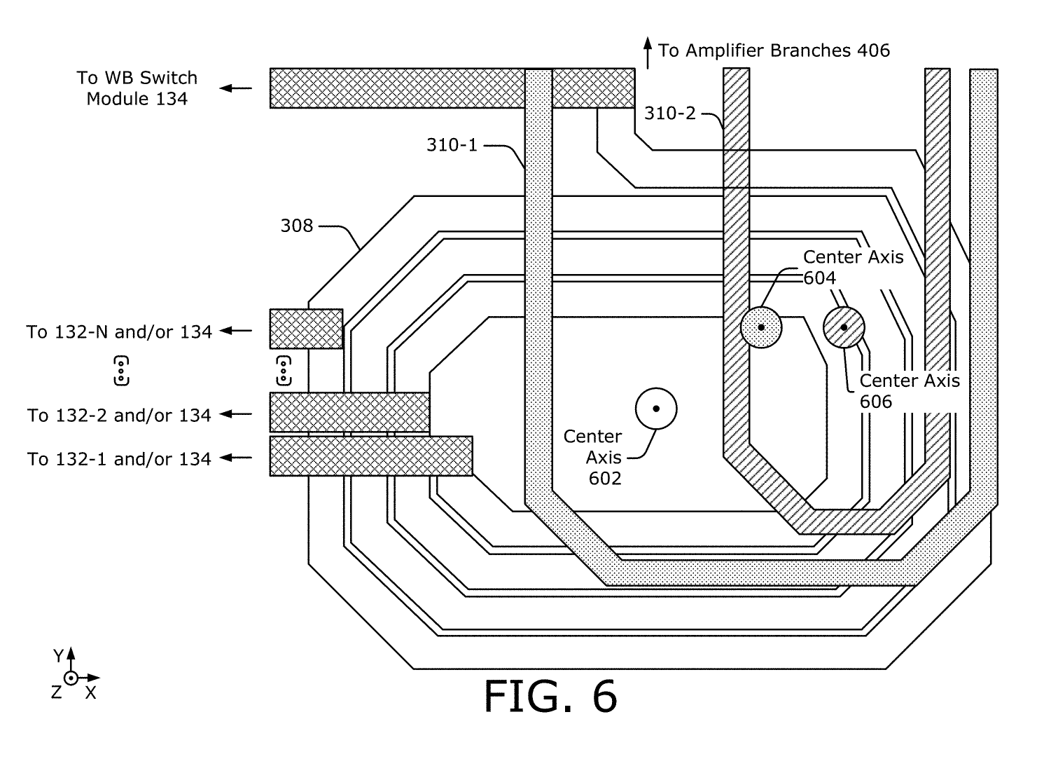

In example implementations, both the input inductor 308 and the degeneration inductors 310-1 to 310-P are implemented on the integrated circuit 302. In general, the input inductor 308 and the degeneration inductors 310-1 to 310-P can have parallel center axes along a z-axis that is perpendicular to a plane that contains the one or more respective coils of each inductor. To achieve a target amount of mutual inductance, the input inductor 308 and the degeneration inductors 310-1 to 310-P can be implemented in a variety of ways to enable a magnetic flux caused by current flowing through one of the inductors to induce a portion of a current in one or more other inductors. The input inductor 308 and the degeneration inductors 310-1 to 310-P can be implemented on one or more different metal layers such that a portion of one of the degeneration inductors 310-1 to 310-P overlaps another portion of the input inductor 308 along the center axis, as described in further detail with respect to FIG. 6.

FIG. 6 illustrates example inductors for gain-dependent impedance matching and linearity. In the depicted configuration, different locations along the input inductor 308, which are represented by the different input nodes 318-1 to 318-N, are connected to different narrowband switch modules 132-1 to 132-N as shown in FIG. 3-2 and/or different switches within the wideband switch module 134, as shown in FIG. 3-3. In this example, the input inductor 308 and the degeneration inductors 310-1 and 310-2 are implemented on different metal layers of the integrated circuit 302. The different layers are illustrated using different patterns. The input inductor 308, the first degeneration inductor 310-1, and the second degeneration inductor 310-2 have one or more coils wrapped around respective center axes, as shown by center axis 602, center axis 604, and center axis 606, respectively. Each of the center axes is parallel to a z-axis that extends into and out of the page (e.g., perpendicular to the page). By controlling a position and orientation of the inductors, the coupling coefficients between the input inductor 308, the first degeneration inductor 310-1, and the second degeneration inductor 310-2 can be precisely set to provide the predetermined impedance matching. Additionally, the on-chip implementation of these inductors can decrease cost and conserve space on the integrated circuit 302. Although two degeneration inductors 310-1 and 310-2 are explicitly depicted in FIG. 6, more than two may be implemented. Furthermore, although the input inductor 308 and the degeneration inductors 310-1 and 310-2 are shown to be on separate metal layers, two or more of these inductors can be implemented on a same metal layer. For example, the input inductor 308 and the degeneration inductors 310-1 can be implemented in a same metal layer such that the input inductor 308 and the degeneration inductor 310-1 are side-by-side along an axis that is perpendicular to the center axis or such that one or more of the degeneration inductors 310-1 to 310-P are disposed inside the input inductor 308. In some implementations, the input inductor 308 and the one or more of the degeneration inductors 310-1 to 310-P are concentric with respect to each other and share a same center axis.

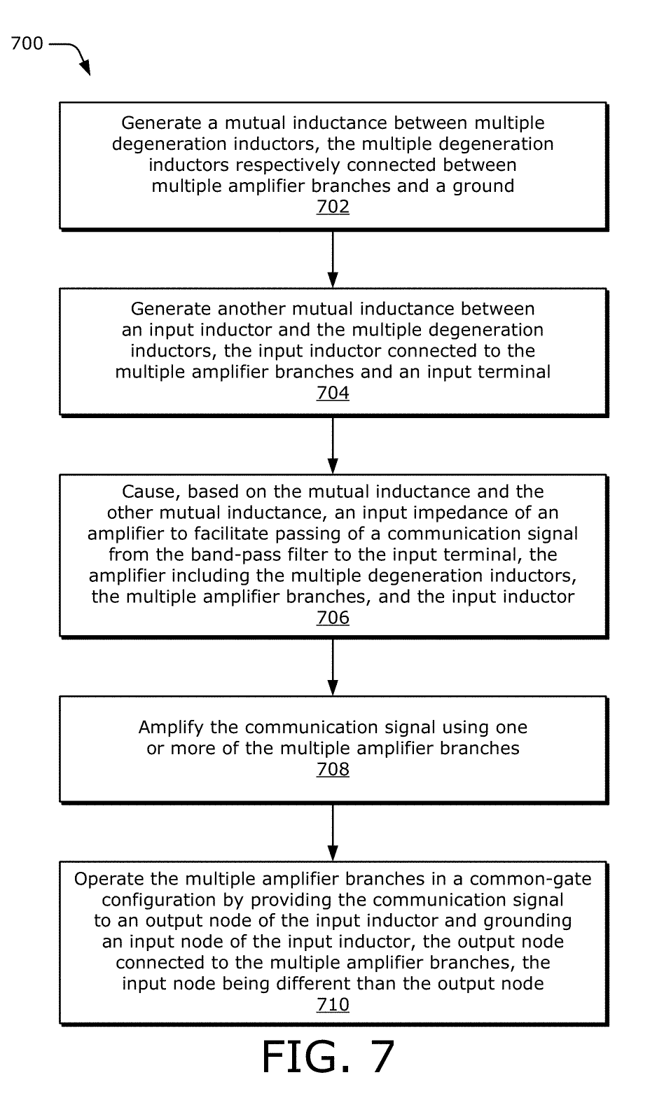

FIG. 7 is a flow diagram illustrating an example process 700 for gain-dependent impedance matching and linearity. The process 700 is described in the form of a set of blocks 702-708 that specify operations that can be performed. However, operations are not necessarily limited to the order shown in FIG. 7 or described herein, for the operations may be implemented in alternative orders or in fully or partially overlapping manners. Operations represented by the illustrated blocks of the process 700 may be performed a low-noise amplifier 126 (e.g., of FIGS. 1-5). More specifically, the operations of the process 700 may be performed by the input inductor 308 and the degeneration inductors 310-1 to 310-N as shown in FIGS. 3-6 in conjunction with the amplifier branches 406-1 to 406-P in FIGS. 4 and 5.

At block 702, a mutual inductance between multiple degeneration inductors is generated. The multiple degeneration inductors are respectively connected between multiple amplifier branches and a ground. For example, the multiple degeneration inductors 310-1 to 310-P in FIG. 4 can be magnetically coupled to each other to generate the mutual inductance via the coupling coefficients K₁₂, K_{2P}, and K_{1P}. The multiple degeneration inductors 310-1 to 310-P can be implemented on a same metal layer or different metal layers of the integrated circuit 302. The multiple degeneration inductors 310-1 to 310-P are connected between the amplifier branches 406-1 to 406-P and the ground 416. As shown via the dot convention of FIGS. 4 and 5, the magnetic flux caused by a current that flows through the first degeneration inductor 310-1 from the first amplifier branch 406-1 to the ground 416 induces a portion of other currents in the second degeneration inductor 310-2 and the Pth degeneration inductor 310-P that respectively flow from the second amplifier branch 406-2 to the ground 416 or from the Pth amplifier branch 406-P to the ground 416.

In general, each amplifier branch 406-1 to 406-P is connected between the output circuit 402 and the ground 416 via one of the parallel branches that includes one of the degeneration inductors 310-1 to 310-P. In some cases, each amplifier branch 406-1 to 406-P is connected to different degeneration inductors 310-1 to 310-P, as shown in FIGS. 4 and 5. In other cases, one or more of the amplifier branches 406-1 to 406-P are connected to a same degeneration inductor 310. While three degeneration inductors 310 and three amplifier branches 406 are explicitly depicted in FIGS. 4 and 5, any number of degeneration inductors 310 and amplifier branches 406 that is greater than or equal to two can be used.

At block 704, another mutual inductance between an input inductor and the multiple degeneration inductors is generated. The input inductor is connected to the multiple amplifier branches and an input terminal. For example, the input inductor 308 in FIG. 4 can be magnetically coupled to each of the multiple degeneration inductors 310-1 to 310-P via the coupling coefficients K₁, K₂, and K_{P}. The input inductor 308 can be implemented on a same metal layer or a different metal layer of the integrated circuit 302 as the multiple degeneration inductors 310.

The input inductor 308 is connected to the amplifier circuit 404 and an input terminal, such as one of the input terminals 316-1 to 316-C or 328 of FIG. 3. For example, the output node 326 of the input inductor 308 is connected to the amplifier circuit 404, as shown in FIG. 4. In particular, the output node 326 of the input inductor 308 can be connected to respective gates of the input transistors 410 of the amplifier branches 406. In one situation, one of the input nodes 318-1 to 318-N of the input inductor 308 is connected to one of the input terminals 316-1 to 316-N via one of the narrowband switch modules 132-1 to 132-N, as shown in FIG. 3-2. In another situation, the output node 326 is connected to the input terminal 328 via the wideband switch module 134, as shown in FIG. 3-3. While the input terminals 316-1 to 316-N can be respectively connected to the band-pass filters 122-1 to 122-C, the input terminal 328 can effectively bypass the band-pass filters 122-1 to 122-C, as shown in FIG. 3-1. Generally speaking, at least a portion of the input inductor 308 is connected between the amplifier circuit 404 and one of the input terminals 316-1 to 316-C or the ground 334. Based on the dot convention shown in FIGS. 4 and 5, the magnetic flux caused by the current that flows through the degeneration inductors 310-1 to 310-P from the amplifier branches 406-1 to 406-P to the ground 416 induces a portion of a current that flows through at least a portion of the input inductor 308 from the input node 318-1 to 318-N to the output node.

At block 706, an input impedance of an amplifier causes the passing of a communication signal from the input terminal to the amplifier to be facilitated based on the mutual inductance and the other mutual inductance. The amplifier includes the multiple degeneration inductors, the multiple amplifier branches, and the input inductor. For example, the mutual inductance between the multiple degeneration inductors 310-1 to 310-P and the other mutual inductance between the input inductor 308 and the multiple degeneration inductors 310-1 to 310-P can contribute to a portion of the real and the imaginary part of the input impedance 320-1 to 320-N of the low-noise amplifier 126 in the common-source configuration, as shown in Equations 4 and 5 via K, n, L_{T}, and L_{Input}. In this way, the input inductor 308 and the multiple degeneration inductors 310-1 to 310-P can enable the low-noise amplifier 126 to achieve a predetermined input impedance 320-1 to 320-N that approximately matches an output impedance of a selected one of the band-pass filter 122-1 to 122-C and/or achieves a target noise figure for the low-noise amplifier 126. This can facilitate propagation of the filtered signal 202-1 to 202-N from the band-pass filter 122-1 to 122-C to the low-noise amplifier 126 (e.g., by reducing losses or noise), thereby improving communication performance of the computing device 102.

Similarly, these mutual inductances also contribute to the input impedance 336 of the low-noise amplifier 126 in the common-gate configuration, as shown in Equations 1 and 2 via gm, L_{T}, and L_{Input}. In this way, the input inductor 308 and the multiple degeneration inductors 310-1 to 310-P can enable the low-noise amplifier 126 to achieve a predetermined input impedance 336 that approximately achieves an input matching at the node 210 and/or a target noise figure for the low-noise amplifier 126. This can facilitate propagation of the wideband signal 214 from the node 210 to the low-noise amplifier 126 (e.g., by reducing losses or noise), thereby improving communication performance of the computing device 102. Generally speaking, the input impedance of the amplifier causes the passing of the communication signal from an input terminal to the amplifier to be facilitated based on the mutual inductance and the other mutual inductance.

At block 708, the communication signal is amplified using the one or more of the multiple amplifier branches. For example, the amplifier branches 406-1 to 406-P can amplify the wideband signal 214 to produce the amplified signal 206. Based on the gain control signal 208, different amplifications of the wideband signal 214 can be achieved by enabling or disabling different combinations of the amplifier branches 406-1 to 406-P.

At block 710, the amplifying of the communication signal comprises operating the multiple amplifier branches in a common-gate configuration by providing the communication signal to an output node of the input inductor and grounding an input node of the input inductor. The output node is connected to the multiple amplifier branches and the input node is different than the output node. For example, the multiple amplifier branches 406-1 to 406-P operate in the common-gate configuration based on the wideband switch module 134 providing the wideband signal 214 to the output node 326 of the input inductor 308 and grounding one of the input nodes 318-1 to 318-N of the input inductor 308, as shown in FIG. 3-3.

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Further, items represented in the accompanying figures and terms discussed herein may be indicative of one or more items or terms, and thus reference may be made interchangeably to single or plural forms of the items and terms in this written description. Finally, although subject matter has been described in language specific to structural features or methodological operations, it is to be understood that the subject matter defined in the appended claims is not necessarily limited to the specific features or operations described above, including not necessarily being limited to the organizations in which features are arranged or the orders in which operations are performed.

What is claimed is:

1. An integrated circuit comprising:
at least two amplifier branches, each amplifier branch of the at least two amplifier branches including:
a node, respective nodes of the at least two amplifier branches connected together;
an input transistor having a gate, a source, and a drain; respective gates of the input transistors of the at least two amplifier branches connected together; and
a cascode stage connected between the drain of the input transistor and the node;
an input inductor connected to the respective gates of the input transistors of the at least two amplifier branches;
at least two degeneration inductors connected between respective sources of the input transistors of the at least two amplifier branches and a ground, the at least two degeneration inductors configured to:
establish a magnetic coupling with the input inductor; and
establish another magnetic coupling between each other;
a first input terminal; and
a wideband switch module comprising:
a switch connected between the first input terminal and an output node of the input inductor, the output node of the input inductor connected to the respective gates of the input transistors of the at least two amplifier branches; and
at least one grounding switch connected between at least one input node of the input inductor and the ground.

2. The integrated circuit of claim 1, wherein:
the at least two amplifier branches include a first input transistor and a second input transistor, the first input transistor having a first gate and a first source, the second input transistor having a second gate and a second source; and
the at least two degeneration inductors include a first degeneration inductor and a second degeneration inductor, the first degeneration inductor connected between the first source of the first input transistor and the ground, the second degeneration inductor connected between the second source of the second input transistor and the ground.

3. The integrated circuit of claim 2, wherein:
the magnetic coupling between the input inductor and the at least two degeneration inductors is configured to induce, based on a first current that flows through the first degeneration inductor from the first source of the first input transistor to the ground or a second current that flows through the second degeneration inductor from the second source of the second input transistor to the ground, a portion of another current that flows through the input inductor from the at least one input node to the output node; and
the other magnetic coupling between the first degeneration inductor and the second degeneration inductor is configured to induce, based on the first current that flows through the first degeneration inductor from the first source of the first input transistor to the ground, a portion of the second current that flows through the second degeneration inductor from the second source of the second input transistor to the ground.

4. The integrated circuit of claim 3, wherein
the at least two amplifier branches, the input inductor, and the at least two degeneration inductors comprise a low-noise amplifier;
the at least two amplifier branches are configured to receive at least one gain control signal that controls different combinations of the first current through the first degeneration inductor and the second current through the second degeneration inductor; and
a total inductance of the at least two degeneration inductors is configured to cause an input impedance of the low-noise amplifier to be substantially similar for the different combinations of the first current and the second current.

5. The integrated circuit of claim 1, wherein:
the at least one input node comprises a first input node of the input inductor and a second input node of the input inductor; and
the at least one grounding switch comprises:
a first grounding switch connected between the first input node of the input inductor and the ground; and
a second grounding switch connected between the second input node of the input inductor and the ground.

6. The integrated circuit of claim 5, wherein the first input node of the input inductor and the second input node of the input inductor comprise different taps on the input inductor.

7. The integrated circuit of claim 5, wherein:
the input inductor comprises a conductor; and
the first input node and the second input node are connected to the conductor at different locations along a length of the conductor.

8. The integrated circuit of claim 7, wherein:
the conductor comprises at least one loop formed about a center axis; and
the first input node and the second input node are connected to the conductor at different points along the at least one loop.

9. The integrated circuit of claim 1, wherein:
the switch and the at least one grounding switch are jointly configured to selectively:
connect the first input terminal to the output node of the input inductor and connect the at least one input node of the input inductor to the ground; or
disconnect the first input terminal from the output node of the input inductor and disconnect the at least one input node of the input inductor from the ground.

10. The integrated circuit of claim 1, further comprising:
a second input terminal configured to connect to a band-pass filter; and
a narrowband switch module connected between the second input terminal and the at least one input node of the input inductor.

11. The integrated circuit of claim 10, wherein:
the first input terminal is configured to bypass the band-pass filter.

12. The integrated circuit of claim 10, wherein:
the wideband switch module is configured to provide an input signal that propagates from the output node of the input inductor to the at least one input node of the input inductor; and
the narrowband switch module is configured to provide another input signal that propagates from the at least one input node of the input inductor to the output node of the input inductor.

13. The integrated circuit of claim 12, wherein:
the wideband switch module is configured to:
cause a first portion of the input signal to be provided at respective sources of the input transistors based on the magnetic coupling between the at least two degeneration inductors and the input inductor; and
cause a second portion of the input signal to be provided at the respective gates of the input transistors, the first portion of the input signal being larger than the second portion of the input signal; and
the narrowband switch module is configured to cause a third portion of the other input signal to be provided at the respective sources of the input transistors based on the magnetic coupling and a fourth portion of the other input signal to be provided at the respective gates of the input transistors, the fourth portion of the other input signal being larger than the third portion of the other input signal.

14. The integrated circuit of claim 13, wherein:
each amplifier branch of the at least two amplifier branches is configured to selectively:
operate in a common-gate configuration with gm-boosting based on the first portion of the input signal being larger than the second portion of the input signal; or
operate in a common-source configuration based on the fourth portion of the other input signal being larger than the third portion of the other input signal.

15. The integrated circuit of claim 1, wherein the input inductor and the at least two degeneration inductors are implemented on different metal layers of the integrated circuit.

16. The integrated circuit of claim 1, wherein the input inductor and each of the at least two degeneration inductors have different center axes that are substantially parallel to each other.

17. The integrated circuit of claim 1, wherein the input inductor and the at least two degeneration inductors have a same center axis.

18. An integrated circuit comprising:
a first input terminal configured to connect to a band-pass filter;
a second input terminal configured to bypass the band-pass filter;
at least two amplifier branches, the at least two amplifier branches including:
a first amplifier branch having a first node, a first input transistor, and a first cascode stage; the first input transistor having a first gate, a first source, and a first drain, the first gate connected to the first input terminal and the first source connected to a ground; the first cascode stage connected between the first drain and the first node; and
a second amplifier branch having a second node, a second input transistor, and a second cascode stage; the second input transistor having a second gate, a second source, and a second drain, the second gate connected to the first gate and the second source connected to the ground; the second cascode stage connected between the second drain and the second node, the second node connected to the first node;
inductive means for magnetically coupling together the first gate, the second gate, the first source, and the second source, the inductive means configured to produce, based on a first current that flows from the first source to the ground and a second current that flows from the second source to the ground, a portion of a third current that flows from the first input terminal towards the first gate and the second gate; and
first switching means for selectively connecting the first gate and the second gate to the first input terminal or the second input terminal.

19. The integrated circuit of claim 18, wherein the inductive means is configured to produce a portion of the second current based on the first current.

20. The integrated circuit of claim 18, wherein:
the at least two amplifier branches and the inductive means comprise a low-noise amplifier; and
the inductive means is configured to selectively cause an input impedance of the low-noise amplifier to match a first output impedance at the first input terminal or a second output impedance at the second input terminal.

21. The integrated circuit of claim 18, further comprising:
a third input terminal configured to connect to another band-pass filter; and
second switching means for selectively connecting the first gate and the second gate to the first input terminal or the third input terminal.

22. The integrated circuit of claim 21, wherein:
the at least two amplifier branches and the inductive means for magnetically coupling comprise a low-noise amplifier; and
the inductive means for magnetically coupling is configured to cause an input impedance of the low-noise amplifier to match an output impedance of the band-pass filter or the other band-pass filter.

23. The integrated circuit of claim 22, wherein:
the at least two amplifier branches are configured to have a first gain associated with the first current being non-zero and the second current being non-zero;
the at least two amplifier branches are configured to have a second gain associated with the first current being zero and the second current being non-zero; and
the inductive means for magnetically coupling is further configured to cause the input impedance of the low-noise amplifier to be substantially similar for the first gain as for the second gain.

24. A method for gain-dependent impedance matching and linearity, the method comprising:
generating a mutual inductance between multiple degeneration inductors, the multiple degeneration inductors respectively connected between multiple amplifier branches and a ground;
generating another mutual inductance between an input inductor and the multiple degeneration inductors, the input inductor connected to the multiple amplifier branches and an input terminal;
causing, based on the mutual inductance and the other mutual inductance, an input impedance of an amplifier to facilitate passing of a communication signal from the input terminal to the amplifier, the amplifier including the multiple degeneration inductors, the multiple amplifier branches, and the input inductor; and
amplifying the communication signal using one or more of the multiple amplifier branches, the amplifying of the communication signal comprising:
operating the multiple amplifier branches in a common-gate configuration by providing the communication signal to an output node of the input inductor and grounding an input node of the input inductor, the output node connected to the multiple amplifier branches, the input node being different than the output node.

25. The method of claim 24, wherein the causing the input impedance of the amplifier to facilitate passing of the communication signal comprises:
causing the input impedance to substantially match an output impedance at the input terminal; and
causing the input impedance to substantially achieve a target noise figure for the amplifier.

26. The method of claim 24, wherein:
the amplifying of the communication signal comprises selectively:
operating the multiple amplifier branches in the common-gate configuration based on a wideband operational mode; or
operating the multiple amplifier branches in a common-source configuration based on a narrowband operational mode by providing the communication signal to the input node of the input inductor.

27. The method of claim 26, wherein:
the operating of the multiple amplifier branches in the common-gate configuration or the operating of the multiple amplifier branches in the common-source configuration is based on a bandwidth of the communication signal.

28. An apparatus comprising:
a node configured to accept a received signal;
a band-pass filter coupled to the node and configured to filter the received signal to produce a filtered signal;
an amplifier circuit including at least two amplifier branches, the amplifier circuit configured to amplify an input signal using one or more of the at least two amplifier branches;
multiple inductors including:
an input inductor having an input node and an output node, the output node connected to the amplifier circuit; and
at least two degeneration inductors respectively connected between the at least two amplifier branches of the amplifier circuit and a ground, the at least two degeneration inductors magnetically coupled to each other and to the input inductor with respective coupling coefficients;
a narrowband switch module connected between the band-pass filter and the input node of the input inductor, the narrowband switch module configured to provide, to the input node of the input inductor, the filtered signal as the input signal; and
a wideband switch module connected to the node, the output node of the input inductor, and the input node of the input inductor; the wideband switch module configured to provide, to the output node of the input inductor, the received signal as the input signal and to connect the input node of the input inductor to the ground.

29. The apparatus of claim 28, wherein:
the amplifier circuit is configured to selectively:
operate in a common-gate configuration based on the wideband switch module providing the received signal; or
operate in a common-source configuration based on the narrowband switch module providing the filtered signal.

30. The apparatus of claim 28, further comprising:
a controller configured to selectively cause the narrowband switch module or the wideband switch module to provide the input signal based on a frequency band range of the received signal.
